(19) United States
(12) Patent Application Publication
(10) Pub. No.: US 2026/0028133 A1
(43) Pub. Date: Jan. 29, 2026

(54) PROTECTIVE SHIELDS FOR SCREENS

(71) Applicant: Gulfstream Aerospace Corporation, Savannah, GA (US)

(72) Inventors: Caleb Wright, Savannah, GA (US); Patrick Leonard, Savannah, GA (US)

(73) Assignee: Gulfstream Aerospace Corporation, Savannah, GA (US)

(21) Appl. No.: 18/787,604

(22) Filed: Jul. 29, 2024

(51) Int. Cl. B64D 43/00; H05K 5/03

(52) U.S. Cl. CPC B64D 43/00; H05K 5/03

(57) ABSTRACT

Aircrafts with kits and methods for servicing aircraft are provided. A method includes covering a display panel in the aircraft with a display shield, wherein the display shield comprises a transparent region configured to allow viewing of the display panel while covered; covering a control panel in the aircraft with a control shield including a transparent region configured to allow viewing of the control panel while covered; employing a tool to service a component of the aircraft while shielding the display panel from the tool with the display shield and shielding the control panel from the tool with the control shield; and reading information displayed on the display panel through the display shield and/or on the control panel through the control shield while servicing the component.

### TECHNICAL FIELD

Embodiments of the subject matter described herein relate generally to protective shields for screens such as in display panels or control panels of the type suitable for use in vehicles, such as aircraft. More particularly, embodiments of the subject matter relate to a kit including removable, temporary, protective shields for protecting screens during servicing of an aircraft.

### BACKGROUND

Modern aircraft are provided with expensive interfaces for exhibiting information and data to pilots and for receiving inputs from the pilots. Increasingly, such interfaces are provided in the form of touch screens. While such screens are manufactured to withstand typical impacts, damage is possible from contact with heavy tools. During servicing of an aircraft, tools may be used in the cockpit. For example, tools may be used in performing general maintenance, diagnostics, or repair of overhead components. If dropped, such tools may impact and damage a screen, which may necessitate an expensive repair.

Accordingly, it is desirable to provide removable, temporary, protective shields for protecting screens during servicing of an aircraft. Furthermore, other desirable features and characteristics of the various embodiments described herein will become apparent from the subsequent detailed description and the appended claims, taken in conjunction with the accompanying drawings and this background.

### BRIEF SUMMARY

In an embodiment, a method for servicing an aircraft is provided. The method includes the method includes covering a display panel in the aircraft with a display shield, wherein the display shield includes a transparent region configured to allow viewing of the display panel while covered; covering a control panel in the aircraft with a control shield including a transparent region configured to allow viewing of the control panel while covered; employing a tool to service a component of the aircraft while shielding the display panel from the tool with the display shield and shielding the control panel from the tool with the control shield; and reading information displayed on the display panel through the display shield and/or on the control panel through the control shield while servicing the component.

In certain embodiments of the method, covering the display panel in the aircraft with the display shield includes engaging an edge of the display shield with a ledge formed in the aircraft.

In certain embodiments of the method, the display shield includes a first section and a separate second section, and covering the display panel in the aircraft with the display shield includes engaging an edge of the first section with a first ledge formed in the aircraft and engaging an edge of the second section with a second ledge formed in the aircraft.

In certain embodiments of the method, the control shield includes tabs formed on opposite ends of the control shield, each tab includes an inward-facing contact, and covering the control panel includes engaging each inward-facing contact with a structure of the aircraft to hold the control shield in place.

In certain embodiments of the method, the control shield includes a frame surrounding the transparent region, and the frame and the tabs are integrally formed.

In certain embodiments of the method, the transparent region is formed with an opening, the control panel includes a projecting instrument that projects from the control panel into a cockpit of the aircraft, and covering the control panel in the aircraft with the control shield includes passing the projecting instrument into or through the opening.

In certain embodiments of the method, the control shield is connected to feet, covering the control panel includes resting the feet on a surface of the aircraft to support the control shield over the control panel.

In certain embodiments of the method, the control shield has a periphery, the control shield is formed with bores spaced along the periphery, and the feet are secured to the control shield with fasteners extending through the bores.

In certain embodiments of the method, each transparent region is polycarbonate resin thermoplastic.

In certain embodiments of the method, the aircraft includes at least three control panels, and the method includes covering each control panel in the aircraft with a respective control shield.

In another embodiment, a kit for protecting components in an aircraft is provided. The kit includes a display shield configured to cover a display panel in the aircraft in an installed configuration of the kit, the display shield includes a transparent region configured to allow viewing of the display panel in the installed configuration; and a plurality of control shields configured to cover a plurality of control panels in the aircraft in the installed configuration, each control shield includes a transparent region configured to allow viewing of a respective control panel in the installed configuration.

In certain embodiments of the kit, the display shield is formed with an edge configured to engage a ledge in the aircraft in the installed configuration.

In certain embodiments of the kit, the display shield includes a first section and a separate second section, the first section is formed with a first edge that engages a ledge of the aircraft in the installed configuration, and the second section is formed with a second edge that engages the ledge of the aircraft in the installed configuration.

In certain embodiments of the kit, each control shield is formed with an opening, each control panel includes a projecting instrument that projects from the respective control panel, and each projecting instrument passes into or through a respective opening in the installed configuration.

In certain embodiments of the kit, the control shield includes tabs formed on opposite ends of the control shield, each tab includes an inward-facing contact configured to engage a structure of the aircraft to hold the control shield in place in the installed configuration.

In certain embodiments of the kit, the control shield includes feet configured to rest on a surface of the aircraft to support the transparent region over the control panel in the installed configuration.

In certain embodiments of the kit, the control shield has a periphery, the control shield is formed with bores spaced along the periphery, and the feet are secured to the control shield with fasteners extending through the bores.

In certain embodiments of the kit, each transparent region is polycarbonate resin thermoplastic.

In certain embodiments of the kit, the aircraft includes at least three control panels, and the kit includes at least three control shields.

In another embodiment, an aircraft is provided. The aircraft includes a cockpit including a display panel and control panels; and a kit for protecting the display panel and the control panels. The kit includes a display shield configured to cover the display panel in an installed configuration, the display shield includes a transparent region configured to allow viewing of the display panel in the installed configuration; and control shields configured to cover the control panels in the installed configuration, each control shield includes a transparent region configured to allow viewing of a respective control panel in the installed configuration, each control shield is formed with an opening, each control panel includes a projecting instrument that projects from the respective control panel, and each projecting instrument passes into or through a respective opening in the installed configuration.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is an exterior side view of an exemplary embodiment of an aircraft having a cockpit protected with a kit as described in embodiments herein;

FIG. 2 is an interior view focused of the cockpit of FIG. 1 including a display panel and control panels, in accordance with embodiments herein;

FIG. 3 is a schematic view of a kit including a display shield and control shields for protecting the display panel and control panels of FIG. 2, in accordance with embodiments herein;

FIG. 4 is a schematic illustrating the kit of FIG. 3 in an installed configuration over the display panel and control panels of the aircraft of FIG. 2 in accordance with embodiments herein;

FIG. 5 is a perspective view of the display panel of FIG. 4 engaged with the vehicle in the installed configuration in accordance with embodiments herein;

FIG. 6 is a cross-sectional schematic view of a control shield in the installed configuration over a control panel in accordance with embodiments herein;

FIG. 7 is an interior view focused of the cockpit of FIG. 1 including a display panel and control panels, in accordance with embodiments herein;

FIG. 8 is a schematic view of a kit including a display shield and control shields for protecting the display panel and control panels of FIG. 7, in accordance with embodiments herein;

FIG. 9 is a schematic illustrating the kit of FIG. 8 in an installed configuration over the display panel and control panels of the aircraft of FIG. 7 in accordance with embodiments herein;

FIG. 10 is a schematic view of a display shield for use in a kit for protecting the display panel of FIG. 7, in accordance with embodiments herein;

FIG. 11 is a cross-sectional schematic view of a display shield in the installed configuration over a display panel in accordance with embodiments herein;

FIG. 12 is a cross-sectional schematic view of a control shield in the installed configuration over a control panel in accordance with embodiments herein; and

FIG. 13 is a flow chart illustrating a method for servicing an aircraft in accordance with embodiments herein.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

The following description may refer to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically. In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

Embodiments herein provide a kit including light-weight, easily-installed, and removable shields. The shields are provided to temporarily cover screens of display units and control units, such as multi-control display units (MCDUs), in a vehicle, such as an aircraft, a train, a bus, or a watercraft. However, it should be appreciated that embodiments of the disclosed removable cover can be utilized for commercial, residential, or other applications. The exemplary implementation shown and described here relates to removable shields provided to protect screens in the cockpit of an aircraft such as during servicing of the aircraft, including diagnostic testing. The shields are transparent, facilitating use of the display units and/or control units while servicing the aircraft without removal of the shields.

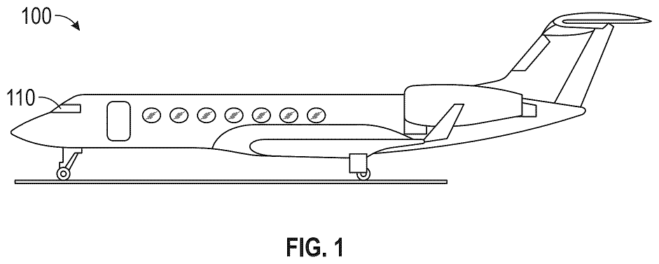

Referring to the drawings, FIG. 1 is a sideview of a vehicle 100, such as an aircraft. As shown, the aircraft 100 includes a cockpit 110.

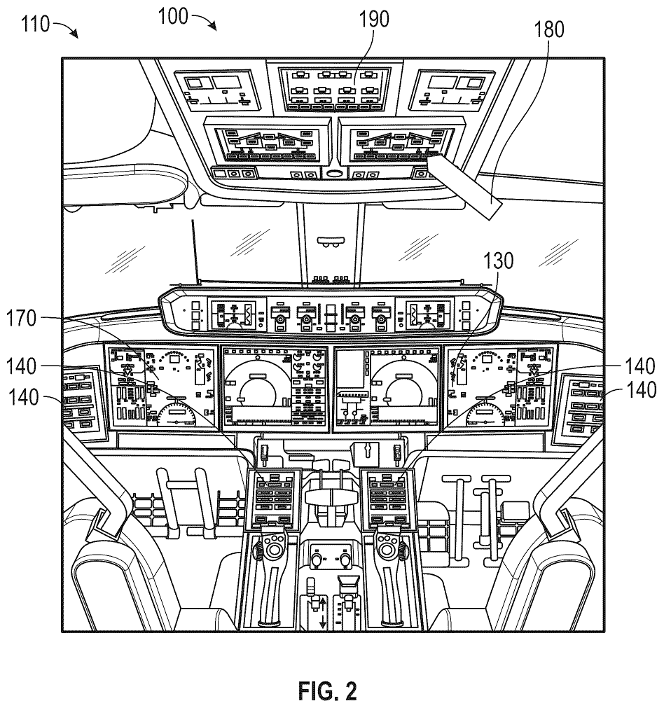

Referring to FIG. 2, an interior view of the cockpit 110 of the aircraft 100 is provided. The aircraft 100 includes components 190, such as overhead components 190, that may be serviced with a tool 180 from within the cockpit 110. As shown, the aircraft 100 further includes a display unit or display panel 130. The display panel 130 may present information or data 170 regarding various conditions of the aircraft 100. As shown, the aircraft 100 further includes control units or control panels 140. In the illustrated embodiment, the aircraft 100 includes four control panels 140, though any desired number of control panels 140 may be provided in the aircraft 100. The control panels 140 may present information or data 170 regarding various conditions of the aircraft 100.

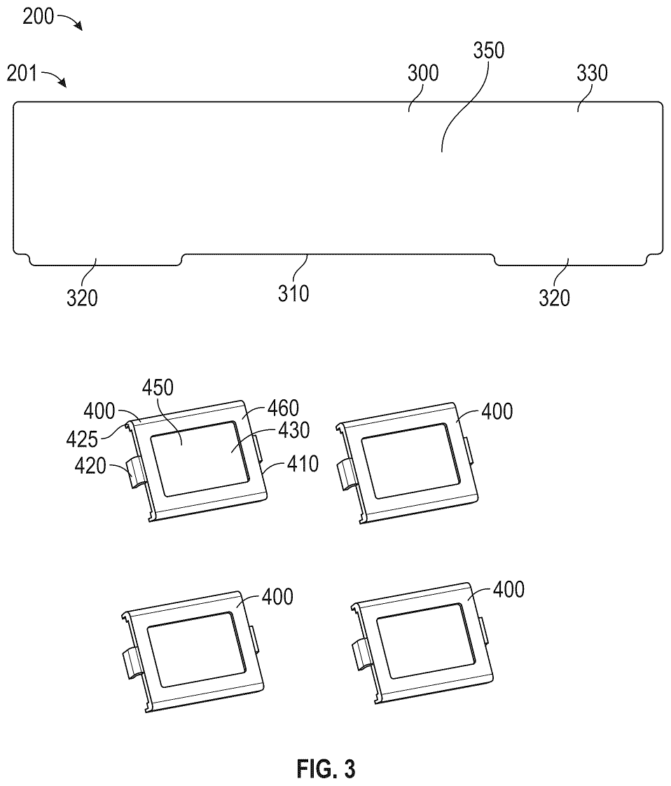

FIG. 3 is a schematic view of a kit 200 including a display shield 300 and a plurality of control shields 400 for protecting the display panel 130 and control panels 140 of the aircraft 100 of FIG. 2. FIG. 3 illustrates the kit 200 in an uninstalled configuration 201.

As shown, the display shield 300 includes a transparent region 350. In certain embodiments, the transparent region 350 is formed by a sheet 330 having a peripheral edge 310. For example, the transparent region 350 may be formed by a polycarbonate resin thermoplastic sheet 330. Further, the display shield 300 may include tabs 320 that extend outward from the periphery. In the embodiment of FIG. 3, a single display shield 300 is formed with dimensions to cover the display panel 130.

As further shown in FIG. 3, the control shields 400 may be identical to one another, such as to cover control panels 140 having a common size and shape. Each control shield 400 may have a transparent region 450. For example, each transparent region 450 may be formed by a polycarbonate resin thermoplastic sheet. Each control shield 400 may further include a frame 460 that surrounds the transparent region 450. The frame 460 may define an outer periphery 410 of each control shield 400. Further, each control shield 400 may be formed with tabs 420 at opposite ends 415. As shown, the tabs 420 may extend downward from the frame 460. Also, the frame 460 may be formed with downward-projecting skirts 425 that extend between the opposite ends 415.

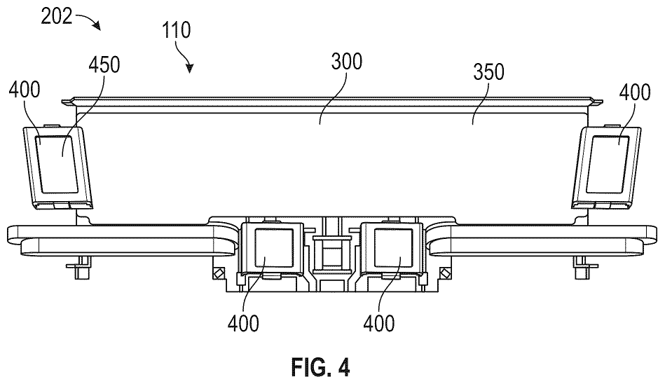

FIG. 4 illustrates the kit 200 of FIG. 3 in an installed configuration 202 in which the display shield 300 covers the display panel 130, and each control shield 400 covers a respective control panel 140. In exemplary embodiments, the transparent regions 350 and 450 of the respective shields 300 and 400 allow a user to view the display panel 130 and control panel 140.

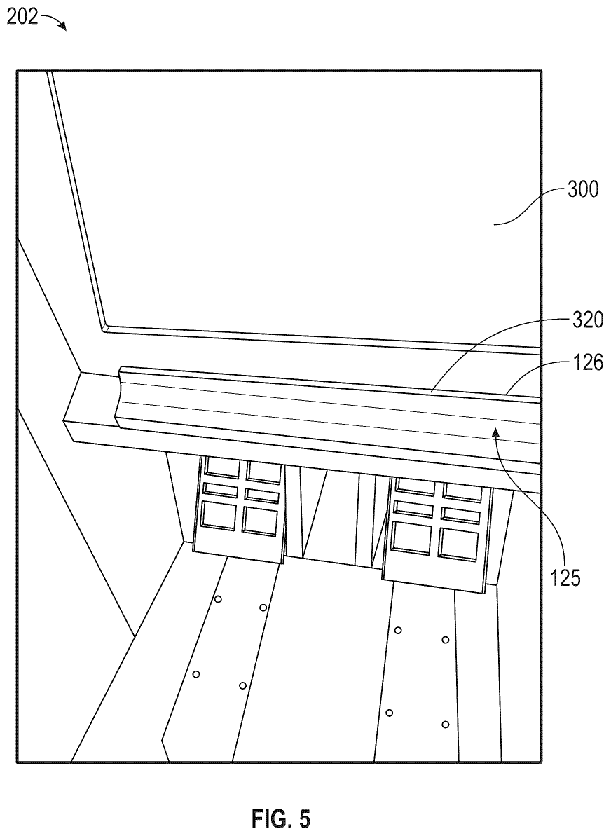

FIG. 5 is a perspective view illustrating the engagement between the display shield 300 and the vehicle 100 in the installed configuration 202. As shown, the vehicle 100 includes a structure 125, such as a ledge 125, separated from the vehicle 100 to form a gap 126. In the installed configuration 202, a tab 320 of the display shield 300 is located in the gap 126 to hold the display shield 300 in the installed configuration 202. The display shield 300 may be removed by lifting the display shield 300 and pulling the tabs 320 from the gaps 126.

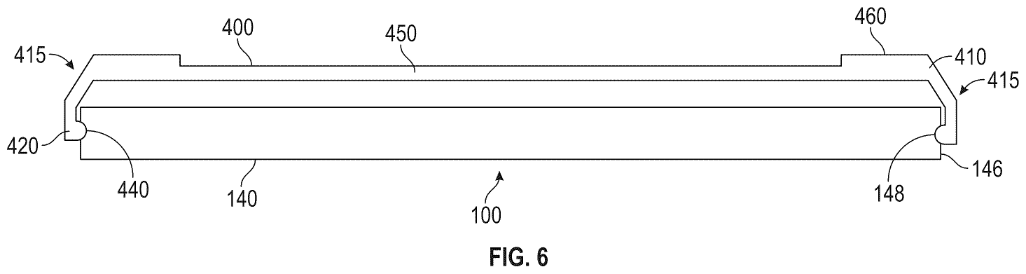

FIG. 6 is a cross-sectional schematic view illustrating the engagement between the control shield 400 of FIG. 3 and the vehicle 100 in the installed configuration 202. As shown, the control panel 140 of the vehicle 100 includes an outer edge 146 formed with a notch 148. Further, each tab 420 of the control shield 400 includes an inward-facing contact 440. In the installed configuration 202, each inward-facing contact 440 may be received in a notch 148 formed in the outer edge 146 of the control panel 140 to hold each control shield 400 in place. Each control shield 400 may be removed by pulling the respective tab 420 away from the outer edge 146 of the control panel 140 to disengage the contact 440 and notch 148.

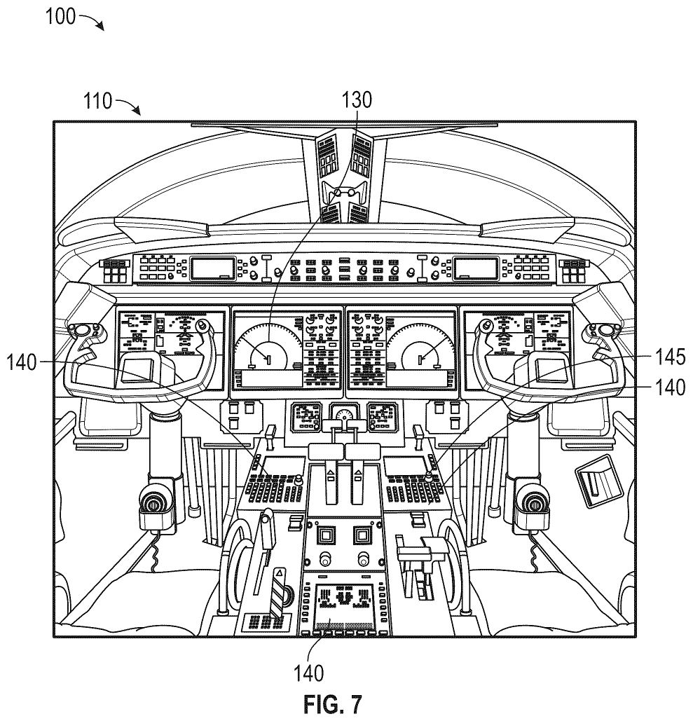

Referring to FIG. 7, an interior view of another embodiment of the cockpit 110 of the aircraft 100 is provided. As shown, the aircraft 100 includes a display unit or display panel 130. Further, the aircraft 100 includes control units or control panels 140. In the illustrated embodiment, the aircraft 100 includes three control panels 140, though any desired number of control panels 140 may be provided in the aircraft 100. In the embodiment of FIG. 7, each control panel 140 is provided with a projecting instrument 145 that projects from the respective control panel 140 into the cockpit 110.

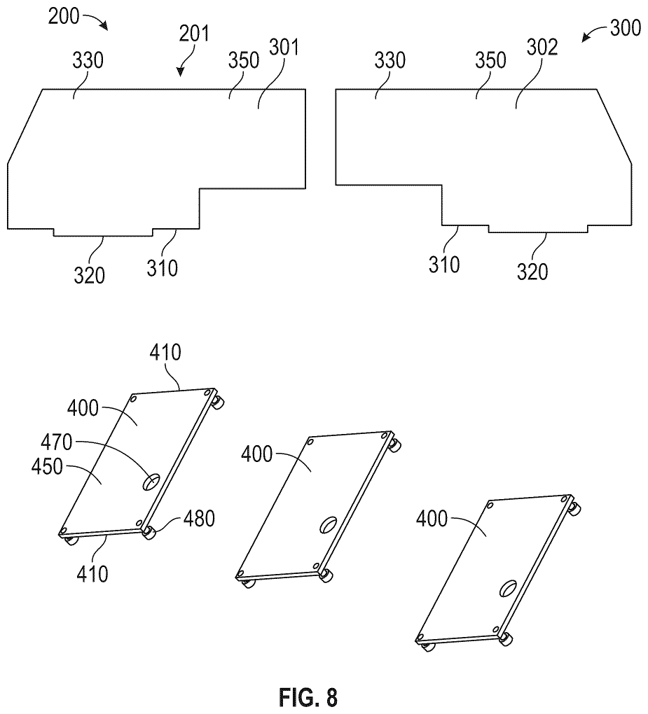

FIG. 8 is a schematic view of a kit 200 including a display shield 300 and a plurality of control shields 400 for protecting the display panel 130 and control panels 140 of the aircraft 100 of FIG. 7. FIG. 8 illustrates the kit 200 in an uninstalled configuration 201.

As shown, the display shield 300 is formed by two separate sections 301 and 302. Each section 301 and 302 includes a transparent region 350. In certain embodiments, the transparent region 350 is formed by a sheet 330 having a peripheral edge 310. In certain embodiments, the transparent region 350 is formed by a polycarbonate resin thermoplastic sheet 330. Further, each section 301 and 302 may include tabs 320 that extend outward from the periphery. In the embodiment of FIG. 8, the combined sections 301 and 302 are formed with dimensions to cover the display panel 130.

As further shown in FIG. 8, the control shields 400 may be identical to one another, such as to cover control panels 140 having a common size and shape. Each control shield 400 may have a transparent region 450 in the form of a sheet. In certain embodiments, the transparent region 450 is formed by a sheet of polycarbonate resin thermoplastic. Each control shield 400 may have a periphery 410, and the periphery 410 may be formed by the transparent region 450. Each control shield 400 may be formed with an opening 470 designed to receive a respective projecting instrument 145. More specifically, each transparent region 450 may be formed with an opening 470 designed to receive a respective projecting instrument 145. Also, each control shield 400 may be connected to, or may include, feet 480. As shown, the feet 480 may be located near the periphery 410.

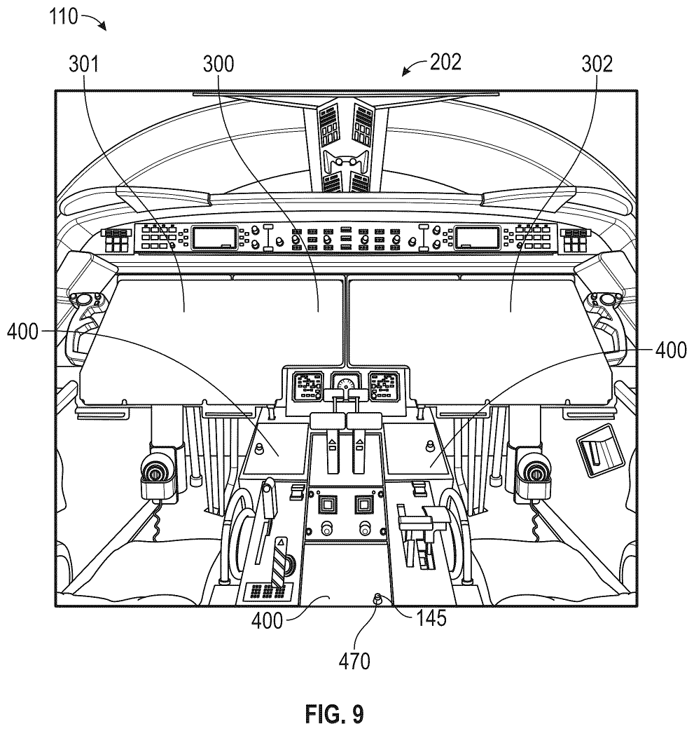

FIG. 9 illustrates the kit 200 of FIG. 8 in an installed configuration 202 in which the display shield 300 covers the display panel 130, and each control shield 400 covers a respective control panel 140. In exemplary embodiments, the transparent regions 350 and 450 of the respective shields 300 and 400 allow a user to view the display panel 130 and control panel 140. As shown in FIG. 9, the projecting instrument 145 of each control panel 140 extends through the opening 470 of each control shield 400.

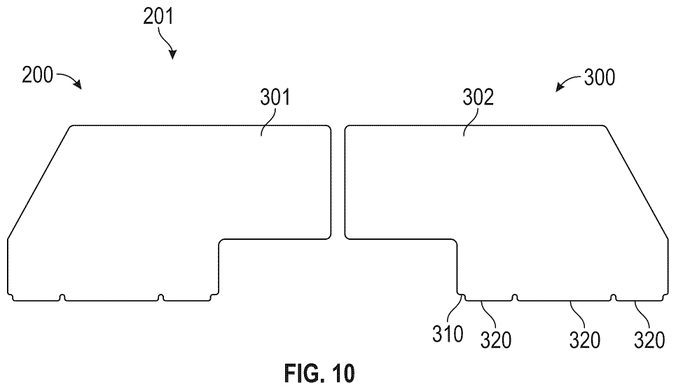

FIG. 10 is a schematic view of a display shield 300 having an alternative design. In FIG. 10, the display shield 300 includes two sections 301, 302. Further, each section 301, 302 is formed with tabs 320 extending from a periphery 310 for engagement with the aircraft. In FIG. 10, the tabs 320 and periphery 310 are designed to fit around and receive handles that are located below the display panel 130 in the aircraft 100.

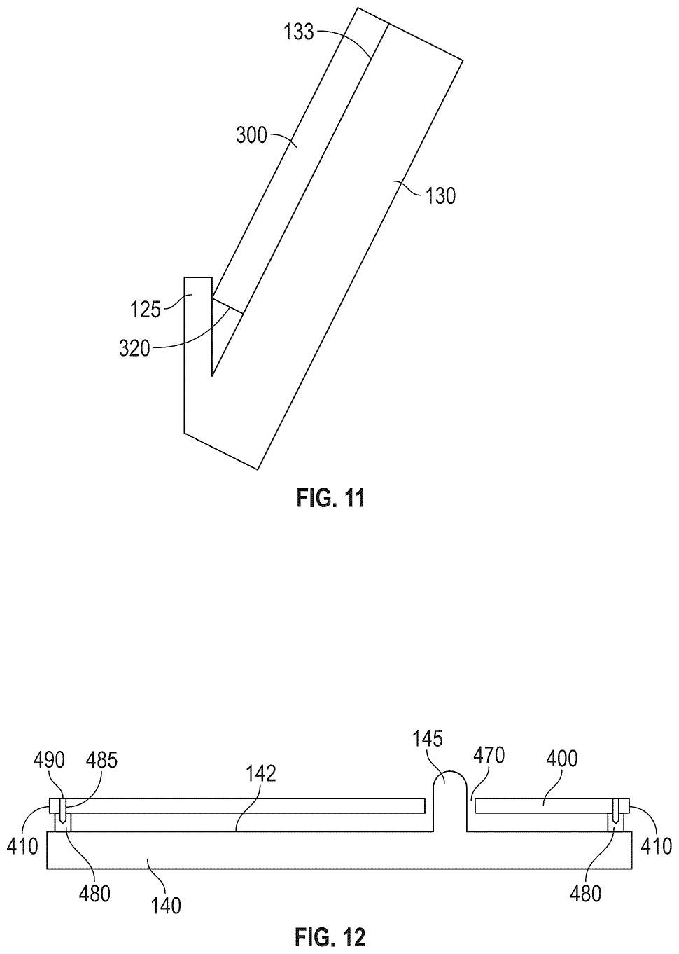

FIG. 11 is a cross-sectional schematic view illustrating the engagement between a display shield 300, such as from FIG. 8 or FIG. 10, and the vehicle 100 in the installed configuration 202. As shown, the vehicle 100 includes a structure 125, such as a ledge 125, separated from a surface 133 of the display panel 130. In the installed configuration 202, a tab 320 of the display shield 300 is located between the surface 133 and the ledge 125 to hold the display shield 300 in the installed configuration 202. The display shield 300 may be removed by lifting the display shield 300 away from the display panel 130 and ledge 125.

FIG. 12 is a cross-sectional schematic view illustrating the engagement between the control shield 400 of FIG. 8 and the vehicle 100 in the installed configuration 202. As shown, the control panel 140 of the vehicle 100 includes an outer surface 142. As shown, each foot 480 contacts and rests on the outer surface 142 in the installed configuration 202. The control shield 400 may be formed with bores 485 near the periphery 410, and a fastener 490 may extend through each bore 485 and into connection with a respective foot 480 to connect the feet 480 to the control shield 400. Further, the projecting instrument 145 of the control panel 140 extends into and/or through the opening 470 formed in the control shield 400. Each control shield 400 may be removed by lifting the control shield 400 away from the outer surface 142 of the control panel 140.

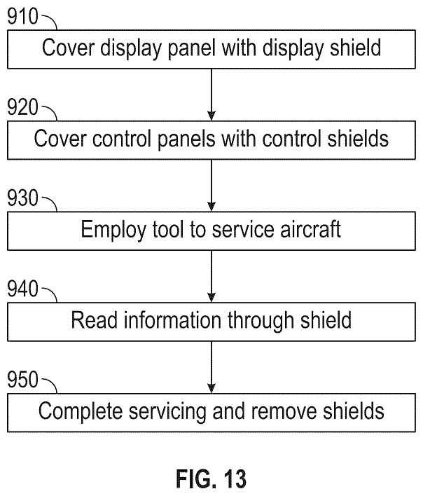

FIG. 13 is a flow chart illustrating a method 900 for servicing an aircraft 100. As shown, method 900 may include, at block 910, covering a display panel 130 in the aircraft 100 with a display shield 300. In certain embodiments, block 910 may include engaging an edge 310 of the display shield 300 with a ledge 125 formed in the aircraft 100.

Method 900 may continue at block 920 with covering a control panel 140 in the aircraft 100 with a control shield 400. In certain embodiments, block 920 includes engaging inward-facing contacts 440 of the control shield 400 with a structure 148 of the aircraft 100 to hold the control shield 400 in place. In certain embodiments, block 920 includes passing a projecting instrument 145 of the control panel 140 into or through an opening 470 in the control shield 400. In certain embodiments, block 920 includes resting feet 480 of the control shield 400 on a surface 142 of the aircraft 100 to support the control shield 400 over the control panel 140.

Method 900 may continue at block 930 with employing a tool 180 to service a component 190 of the aircraft 100 while shielding the display panel 130 from the tool 180 with the display shield 300 and shielding the control panel 140 from the tool 180 with the control shield 400.

Method 900 may further include, at block 940, reading information 170 displayed on the display panel 130 through the transparent region of the display shield 300 and/or on the control panel 140 through the transparent region of the control shield 400 while servicing the component 190.

Method 900 may continue at block 950 with completing servicing of the aircraft and removing the shields 300 and 400 from the cockpit 110. Block 950 may further include storing the shields 300 and 400 with ground support equipment.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for servicing an aircraft 100, the method comprising:
covering a display panel 130 in the aircraft 100 with a display shield 300, wherein the display shield 300 comprises a first transparent region 350 configured to allow viewing of the display panel 130 while covered;
covering a control panel 140 in the aircraft 100 with a control shield 400 comprising a second transparent region 450 configured to allow viewing of the control panel 140 while covered;
employing a tool 180 to service a component 190 of the aircraft 100 while shielding the display panel 130 from the tool 180 with the display shield 300 and shielding the control panel 140 from the tool 180 with the control shield 400; and
reading information displayed on the display panel 130 through the display shield 300 and/or on the control panel 140 through the control shield 400 while servicing the component 190.

2. The method of claim 1, wherein covering the display panel 130 in the aircraft 100 with the display shield 300 comprises engaging an edge 310 of the display shield 300 with a ledge 125 formed in the aircraft 100.

3. The method of claim 1, wherein the display shield 300 comprises a first section 301 and a separate second section 302, and wherein covering the display panel 130 in the aircraft 100 with the display shield 300 comprises engaging an edge 310 of the first section 301 with a first ledge 125 formed in the aircraft 100 and engaging an edge 310 of the second section 302 with a second ledge 125 formed in the aircraft 100.

4. The method of claim 1, wherein the control shield 400 comprises tabs 420 formed on opposite ends 415 of the control shield 400, wherein each tab 420 includes an inward-facing contact 440, and wherein covering the control panel 140 comprises engaging each inward-facing contact 440 with a structure 148 of the aircraft 100 to hold the control shield 400 in place.

5. The method of claim 4, wherein the control shield 400 includes a frame 460 surrounding the transparent region 450, and wherein the frame 460 and the tabs 420 are integrally formed.

6. The method of claim 1, wherein the transparent region 450 is formed with an opening 470, wherein the control panel 140 includes a projecting instrument 145 that projects from the control panel 140 into a cockpit 110 of the aircraft 100, and wherein covering the control panel 140 in the aircraft 100 with the control shield 400 comprises fitting the projecting instrument 145 into or through the opening 470.

7. The method of claim 1, wherein the control shield 400 is connected to feet 480, wherein covering the control panel 140 comprises resting the feet 480 on a surface 142 of the aircraft 100 to support the control shield 400 over the control panel 140.

8. The method of claim 7, wherein the control shield 400 has a periphery 410, wherein the control shield 400 is formed with bores 485 spaced along the periphery 410, and wherein the feet 480 are secured to the control shield 400 with fasteners 490 extending through the bores 485.

9. The method of claim 1, wherein each transparent region 350/450 is polycarbonate resin thermoplastic.

10. The method of claim 1, wherein the aircraft 100 includes at least three control panels 140, and wherein the method comprises covering each control panel 140 in the aircraft with a respective control shield 400.

11. A kit 200 for protecting components 130/140 in an aircraft 100, the kit 200 comprising:
a display shield 300 configured to cover a display panel 130 in the aircraft 100 in an installed configuration 202 of the kit 200, wherein the display shield 300 comprises a first transparent region 350 configured to allow viewing of the display panel 130 in the installed configuration 202; and
a plurality of control shields 400 configured to cover a plurality of control panels 140 in the aircraft 100 in the installed configuration 202, wherein each control shield 400 comprises a respective second transparent region 450 configured to allow viewing of a respective control panel 140 in the installed configuration 202.

12. The kit 200 of claim 11, wherein the display shield 300 is formed with an edge 310 configured to engage a ledge 125 in the aircraft 100 in the installed configuration 202.

13. The kit 200 of claim 11, wherein the display shield 300 comprises a first section 301 and a separate second section 302, wherein the first section 301 is formed with a first edge 310 that engages a ledge 125 of the aircraft in the installed configuration, and wherein the second section 302 is formed with a second edge 310 that engages the ledge 125 of the aircraft 100 in the installed configuration 202.

14. The kit 200 of claim 11, wherein each control shield 400 is formed with an opening 470, wherein each control panel 140 includes a projecting instrument 145 that projects from the respective control panel 140, and wherein each projecting instrument 145 projects into or through a respective opening 470 in the installed configuration 202.

15. The kit 200 of claim 11, wherein the control shield 400 comprises tabs 420 formed on opposite ends 415 of the control shield 400, wherein each tab 420 includes an inward-facing contact 440 configured to engage a structure 148 of the aircraft 100 to hold the control shield 400 in place in the installed configuration 202.

16. The kit 200 of claim 11, wherein the control shield 400 comprises feet 480 configured to rest on a surface 142 of the aircraft 100 to support the transparent region 450 over the control panel 140 in the installed configuration 202.

17. The kit 200 of claim 16, wherein the control shield 400 has a periphery 410, wherein the control shield 400 is formed with bores 485 spaced along the periphery 410, and wherein the feet 480 are secured to the control shield 400 with fasteners 490 extending through the bores 485.

18. The kit 200 of claim 11, wherein each transparent region 350/450 is polycarbonate resin thermoplastic.

19. The kit 200 of claim 11, wherein the aircraft 100 includes at least three control panels 140, and wherein the kit 200 comprises at least three control shields 400.

20. An aircraft 100 comprising:
a cockpit 110 including a display panel 130 and control panels 140; and
a kit 200 for protecting the display panel 130 and the control panels 140, wherein the kit 200 comprises:
a display shield 300 configured to cover the display panel 130 in an installed configuration 202, wherein the display shield 300 comprises a first transparent region 350 configured to allow viewing of the display panel 130 in the installed configuration 202; and
control shields 400 configured to cover the control panels 140 in the installed configuration 202, wherein each control shield 400 comprises a second transparent region 450 configured to allow viewing of a respective control panel 140 in the installed configuration 202, wherein each control shield 400 is formed with an opening 470, wherein each control panel 140 includes a projecting instrument 145 that projects from the respective control panel 140, and wherein each projecting instrument 145 passes into or through a respective opening 470 in the installed configuration 202.
